(19) United States
(12) Patent Application Publication
(10) Pub. No.: US 2026/0185234 A1
(43) Pub. Date: Jul. 2, 2026

(54) FILM FORMING COMPOSITIONS AND METHODS AND SYSTEMS FOR FORMING LOW DIELECTRIC CONSTANT FILMS

(71) Applicant: ASM IP Holding B.V., Almere (NL)

(72) Inventors: Hirotsugu Sugiura, Tokyo (JP); Miho Majima, Tokyo (JP); Ippei Yanagisawa, Sagamihara-shi (JP); Yoshiyuki Kikuchi, Tokyo (JP); Yingtong Bao, Tokyo (JP); Lingjun Xue, Tokyo (JP)

(21) Appl. No.: 19/434,154

(22) Filed: Dec. 29, 2025

Related U.S. Application Data
(60) Provisional application No. 63/740,431, filed on Dec. 31, 2024.

(51) Int. Cl. C23C 16/505; C23C 16/455; C23C 16/458; C23C 16/52

(52) U.S. Cl. CPC C23C 16/505; C23C 16/455; C23C 16/458; C23C 16/52

(57) ABSTRACT

Film forming compositions that are configured for forming a low-k material film with a reduced propensity for plasma induced damage are provided. The film forming compositions comprise a silicon precursor that has a structure according to general Formula (1):

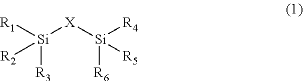

wherein, X is selected from an O atom, an NH group, and a CH₂ group; and R¹, R², R³, R⁴, R⁵, and R⁶ are each a substituent group independently selected from a hydrogen atom, a C₁-C₆ alkyl group, a C₂-C₆ alkenyl group, and a C₁-C₆ alkoxy group with the proviso that at least one of R¹, R², R³, R⁴, R⁵, and R⁶ is a methyl group (CH₃). Preferably, at least two of R¹, R², R³, R⁴, R⁵, and R⁶ are methyl groups. Methods and systems for forming a low-k material film on a surface of a substrate using a PE-CVD method are also provided.

### CROSS-REFERENCE TO RELATED APPLICATIONS

This application claims priority to U.S. Provisional Patent Application Ser. No. 63/740,431 filed Dec. 31, 2024 and titled FILM FORMING COMPOSITIONS AND METHODS AND SYSTEMS FOR FORMING LOW DIELECTRIC CONSTANT FILMS, the disclosure of which is hereby incorporated by reference in its entirety.

### FIELD

The present disclosure generally relates to the field of semiconductor processing methods and systems. In particular, the present disclosure generally relates to the formation of low-k material films with reduced propensity to plasma induced damage.

### BACKGROUND

Low-k materials have long been utilized as inter-layer dielectrics in semiconductor manufacturing to reduce parasitic capacitance and improve device performance. As the industry advances toward increasingly smaller nodes, the reduction of plasma-induced damage (PID) during patterning and etching processes has become a critical concern. This is because PID can significantly alter the dielectric properties of low-k materials, especially as feature sizes shrink and the relative impact of damaged regions becomes more pronounced. In smaller geometries, even thin layers of PID can disproportionately affect the overall dielectric constant, leading to degraded electrical performance and reliability issues. As a result, there is a growing emphasis on developing materials and processes that not only achieve lower k-values but also exhibit enhanced resistance to plasma exposure. Addressing these challenges requires innovative approaches to film deposition and integration. In this context, the present disclosure relates to film-forming compositions, along with corresponding methods and systems, that are specifically designed to meet the evolving demands of next-generation semiconductor devices by minimizing PID and optimizing dielectric performance. Any discussion, including discussion of problems and solutions, set forth in this section has been included in this disclosure solely for the purpose of providing a context for the present disclosure. Such discussion should not betaken as an admission that any of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to a film forming composition that is configured for forming a low-k material film and to a method and a system for using said composition to form a low-k material film. The low-k material film may beneficially have a reduced propensity to plasma induced damage.

An aspect of the present disclosure relates to a film forming composition that comprises a silicon precursor having a structure according to a general Formula (1):

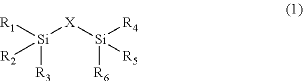

wherein, X is selected from an O atom, an NH group, and a CH₂ group; and R¹, R², R³, R⁴, R⁵, and R⁶ are each a substituent group independently selected from a hydrogen atom, a C₁-C₆ alkyl group, a C₂-C₆ alkenyl group, and a C₁-C₆ alkoxy group with the proviso that at least one of R¹, R², R³, R⁴, R⁵, and R⁶ is a methyl group (CH₃). In some embodiments, at least two of R¹, R², R³, R⁴, R⁵, and R⁶ are methyl groups. In some embodiments, at least four of R¹, R², R³, R⁴, R⁵, and R⁶ are methyl groups.

In some embodiments, X is an O atom.

In some embodiments, X is an NH group.

In some embodiments, X is a CH₂ group.

In some embodiments, the substituent R¹ is selected from a C₂-C₆ alkenyl group and a C₁-C₆ alkoxy group; and the substituents R², R³, R⁴, R⁵, and R⁶ are each independently selected from a hydrogen atom and a C₁-C₆ alkyl group with the proviso that at least one of R², R³, R⁴, R⁵, and R⁶ is a methyl group. In some of these embodiments, at least two of R², R³, R⁴, R⁵, and R⁶ are methyl groups. In some of these embodiments, R² and R³ are methyl groups. In some of these embodiments, at least four of R², R³, R⁴, R⁵, and R⁶ are methyl groups. In some of these embodiments, R², R³, R⁵, and R⁶ are methyl groups.

In some embodiments, the substituents R¹ and R⁴ are each selected from a C₂-C₆ alkenyl group and a C₁-C₆ alkoxy group; and the substituents R², R³, R⁵, and R⁶ are each independently selected from a hydrogen atom and a C₁-C₆ alkyl group with the proviso that at least one of R², R³, R⁵, and R⁶ is a methyl group. In some of these embodiments, at least two of R², R³, R⁵, and R⁶ are methyl groups. In some of these embodiments, at least four of R², R³, R⁵, and R⁶ are methyl groups.

In some embodiments, the silicon precursor is selected from the group consisting of 1,3-dimethyl-1,3-divinyldisiloxane, 1,1,3,3-tetramethyl-1-vinyldisiloxane, 1,1,3,3,3-pentamethyl-1-vinyldisiloxane, 1,1,3,3-tetramethyl-1,3-divinyldisiloxane, 4-methyl-1,1,3,3-tetramethyldisiloxane, 4-ethyl-1,1,3,3-tetramethyldisiloxane, 4-methyl-1,1,1,3,3-pentamethyldisiloxane, 4-ethyl-1,1,1,3,3-pentamethyldisiloxane, 1,3-dimethoxy-1,3-dimethyldisiloxane, 1,3-diethoxy-1,3-dimethyldisiloxane, 1,3-dimethoxy-1,1,3,3-tetramethyldisiloxane, 1,3-diethoxy-1,1,3,3-tetramethyldisiloxane, 1,3-divinyl-1,3-dimethyl-1,3-dimethoxydisiloxane, 1,1,3,3-tetramethyldisiloxane, and hexamethyldisiloxane.

In some embodiments, the silicon precursor is selected from the group consisting of 1,3-dimethyl-1-vinyldisilazane, 1,1,3,3-tetramethyl-1-vinyldisilazane, 1,1,3,3,3-pentamethyl-1-vinyldisilazane, 1,3-dimethyl-1,3-divinyldisilazane, 1,1,3,3-tetramethyl-1,3-divinyldisilazane, 1,1,3,3-tetramethyldisilazane, and hexamethyldisilazane.

In some embodiments, the silicon precursor is selected from the group consisting of 2,4,4-trimethyl-5-oxa-2,4-disilahexane, 2,4,4-trimethyl-5-oxa-2,4-disilaheptane, 2,2,4,4-tetramethyl-5-oxa-2,4-disilahexane, 2,2,4,4-tetramethyl-5-oxa-2,4-disilaheptane, 3,3,5,5-tetramethyl-2,6-dioxa-3,5-disilaheptane, 3,3,5,5-tetramethyl-2,6-dioxa-3,5-disilanonane, 3,5-dimethoxy-3,5-dimethyl-2,6-dioxa-3,5-disilaheptane, ((dimethoxymethylsilyl)methyl)trimethylsilane, and ((methoxymethylsilyl)methyl)ethenyldimethylsilane.

In some embodiments, the film forming composition has a purity of at least about 95 wt. % (based on the weight of the silicon precursor). The film forming composition may have a purity of at least about 95 wt. %, or at least about 97 wt. %, or at least about 98 wt. %, or at least about 99 wt. %, or at least about 99.5 wt. %, or at least about 99.9 wt. %, or at least about 99.99 wt. % (based on the weight of the silicon precursor).

Another aspect of the present disclosure relates to a precursor delivery vessel that comprises the film forming composition described in any of the above paragraphs. The precursor delivery vessel comprises an outer wall that encloses a cavity for storing the film forming composition and an outlet for allowing a flow of the film forming composition to exit the cavity. The outlet is seated in the outer wall of the precursor delivery vessel and is in communication with the cavity of the precursor delivery vessel and has at least one valve positioned thereon to fluidly couple or decouple the cavity to the outside environment.

Another aspect of the disclosure relates to a method of forming a low-k material film on a surface of a substrate via a PE-CVD process. The method comprises introducing a vapor of the film forming composition described in any of the above related paragraphs into a reaction chamber; optionally introducing a feed gas into the reaction chamber, and forming a plasma in the reaction chamber, thereby forming a low-k material film on a surface of the substrate. In some embodiments, the step of introducing a vapor of the film forming composition, optionally introducing the feed gas, and the step of forming a plasma in the reaction chamber at least partially overlap.

In some embodiments, method comprises introducing a vapor of the film forming composition, introducing the feed gas, and forming a plasma in the reaction chamber.

In some embodiments, the method further comprises maintaining the reaction chamber at a pressure of at least about 0.5 Torr and no more than about 100 Torr.

In some embodiments, the method further comprises maintaining a temperature of the substrate at least about 50° C. and no more than about 500° C.

In some embodiments, the plasma comprises a capacitively coupled plasma (CCP).

In some embodiments, a ratio of the silicon precursor to the feed gas is between 5:1 and 1:40, or between 5:1 and 1:30, or between 5:1 and 1:20.

In some embodiments, the feed gas comprises a noble gas. In some embodiments, the feed gas comprises a noble gas and an oxygen-containing gas.

In some embodiments, the feed gas comprises an oxygen-containing gas. In some embodiments, a ratio of the silicon precursor to the oxygen containing gas is between 100:1 and 1:1, or between 20:1 and 1:1, or between 10:1 and 1:1, or between 2:1 and 1:1.

In some embodiments, the feed gas comprises an oxygen-containing gas comprising one or more of nitrous oxide (N₂O), nitrogen dioxide (NO₂), nitric oxide (NO), oxygen (O₂), ozone (O₃), carbon dioxide (CO₂), carbon monoxide (CO), and mixtures thereof.

In some embodiments, the feed gas comprises N₂O. In some embodiments, the feed gas comprises N₂O and Ar. In some of these embodiments, the feed gas further comprises O₂, wherein a ratio of N₂O to O₂ is between 20:1 and 2:1.

In some embodiments, the feed gas comprises Ar, He, or mixtures thereof. In some embodiments, the feed gas comprises N₂O, O₂, Ar, He, or mixtures thereof.

In some embodiments, the plasma is formed by applying a high-frequency RF power and/or a low-frequency RF power, wherein a frequency of the high-frequency RF power is at least about 13.56 MHz and a frequency of the low-frequency RF power is no more than about 2 MHz.

In some embodiments, a process gap of the reaction chamber is between about 5 mm and about 30 mm.

In some embodiments, the method further comprises irradiating the surface of the substrate with UV radiation.

In some embodiments, the low-k material film comprises silicon, oxygen, and carbon. In some embodiments, a low-k material film comprises silicon oxycarbide. In some embodiments, the low-k material film comprises at least about 20 at. % of carbon, at least about 30 at. % of carbon, or at least about 40 at. % of carbon, or at least about 50 at. % of carbon.

Another aspect of the disclosure relates to a substrate processing apparatus for forming a low-k material film on a surface of a substrate via a PE-CVD process using the film forming composition and the methods described in any of the above related paragraphs. The substrate processing apparatus comprises a vapor deposition assembly that comprises a reaction chamber comprising a first susceptor for accommodating a substrate, a film forming composition source comprising a film forming composition in fluid communication with the reaction chamber via a film forming composition source valve, a feed gas source comprising a feed gas in fluid communication with the reaction chamber via a feed gas source valve, a plasma unit comprising a power generator, and a controller operably connected to the film forming composition source valve, the feed gas source valve, and the power generator. The controller is configured and programmed to control supplying the film forming composition to the reaction chamber, supplying the feed gas to the reaction chamber; and activating the power generator to form a plasma in the reaction chamber to form a low-k material film on a surface of a substrate. In some embodiments, the steps of supplying the film forming composition, supplying the feed gas, and activating the power generator at least partially overlap.

In some embodiments, the substrate processing apparatus further comprises a UV curing assembly comprising a curing chamber comprising a second susceptor for accommodating the substrate and one or more UV lamps positioned above the second susceptor, wherein the controller is operably connected to the one or more UV lamps and configured and programmed to control irradiating the low-k material film formed on the surface of the substrate with UV radiation.

These and other embodiments will be readily apparent to those skilled in the art from the following detailed description of certain embodiments and with further reference to the attached figures. These embodiments or components thereof may be combined, or they may be applied separately from each other, as applicable, unless otherwise noted. The invention is not limited to any particular embodiments disclosed.

### BRIEF DESCRIPTION OF DRAWINGS

The accompanying drawings constitute part of the specification. The drawings are included to provide a further understanding of the disclosure, and together with the description explain certain principles of the disclosure. The drawings illustrate exemplary embodiments of how the disclosure can be made and used and are not to be construed as limiting the disclosure to only the illustrated and described examples. It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure. Further features and advantages will become apparent from the following, more detailed, description of various aspects, embodiments, and configurations of the disclosure, as illustrated by the drawings referenced below.

FIG. 1 is a process flow diagram of a method for forming a low-k material film on a surface of a substrate according to an embodiment of the present disclosure. Optional steps are shown by the features or elements in the dashed lines.

FIG. 2 is a process flow diagram of a method for forming a low-k material film on a surface of a substrate according to another embodiment of the present disclosure. Optional steps are shown by the features or elements in the dashed lines.

FIG. 3 is a schematic presentation of a vapor deposition assembly according to an embodiment of the present disclosure.

FIG. 4 shows the PID layer thickness versus k-value for low-k material films formed according to methods of the present disclosure (triangles) compared to a conventional method (circles).

FIG. 5 shows the PID layer thickness versus k-value for low-k material films formed according to methods of the present disclosure using an O₂ containing feed gas (circles) versus an N₂O containing feed gas (diamonds).

### DETAILED DESCRIPTION

The description of embodiments of film forming compositions, methods, and systems provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. Unless otherwise noted, the exemplary embodiments or components thereof may be combined or may be applied separately from each other. The headings provided herein, if any, are for convenience only and do not necessarily affect the scope or meaning of the claimed invention.

As used herein, “chemical vapor deposition”, abbreviated as “CVD”, refers to a vapor deposition process in which a film is deposited on a substrate by exposing its surface to one or more gaseous precursors and reactants, which react and/or decompose near and/or on the substrate surface to form the film. The precursors and/or reactants can be provided simultaneously to the reaction chamber, or in partially or completely separated pulses. In some embodiments, the precursors and/or reactants are provided until a layer having a desired thickness and/or uniformity is deposited. In some embodiments, a cyclic CVD process can be used with multiple cycles to deposit a thin film having a desired thickness.

As used herein, a “cyclic deposition process” refers to a method or a process comprising sequentially introducing precursors and/or reactants into a reaction chamber to deposit a layer or a film on or over a substrate and includes processing techniques such as cyclical CVD.

As used herein, a “film” or “layer”, which may be used interchangeably, refers to a continuous, substantially continuous, or non-continuous material that extends in a direction perpendicular to a thickness direction to cover at least a portion of a surface. A film may be positioned on a lateral surface and/or on a sidewall of recessed features of a surface. A film can include two-dimensional materials, three-dimensional materials, nanoparticles, partial or full molecular layers, partial or full atomic layers, and/or clusters of atoms or molecules. A film may be built up from one or more indiscernible monolayers or sub-monolayers to produce a uniform or a substantially uniform material, wherein the number of monolayers or sub-monolayers influences the thickness of the film.

As used herein, a “gas” refers to a state of matter consisting of atoms or molecules that have neither a defined volume nor shape. A gas includes vaporized solid and/or liquid and may be referred to as a vapor. A gas may be constituted by a single gas or a mixture of gases, depending on the context.

As used herein, a “precursor” refers to a compound that participates in a chemical reaction to form another compound or element, wherein a portion of the precursor (an element or group within the precursor) is incorporated into the compound or element that results from the chemical reaction. The compound or element that results from the chemical reaction may be a layer and/or a film that is formed on a surface of a substrate.

As used herein, the term “purge” refers to a procedure in which vapor phase precursors, reactants, and/or vapor phase byproducts are removed from a substrate surface, for example, by evacuating the reaction chamber with a vacuum pump and/or by replacing the gas inside a reaction chamber with an inert or substantially inert gas such as argon or nitrogen. Purging may be effected between two pulses of gases which react with each other. Purging may also be effected between two pulses of gases that do not react with each other. For example, a purge or purging may be provided between pulses of two precursors or between a precursor and a reactant. Purging may avoid or at least reduce gas-phase interactions between the two gases reacting with each other. It shall be understood that a purge can be effected either in time or in space, or both. For example, in the case of temporal purges, a purge step can be used, for example, in a temporal sequence of providing a first reactant to a reaction chamber, providing a purge gas to the reaction chamber, and providing a second reactant to the reaction chamber, wherein the substrate on which a layer is deposited does not move. For example, in the case of spatial purges, a purge step can comprise moving a substrate from a first location to which a first reactant is continually supplied, through a purge gas curtain, to a second location to which a second reactant is continually supplied.

As used herein, a “reactant” refers to a compound that participates in a chemical reaction to form another compound or element. In some instances, a reactant is a precursor. In other instances, the compound or element that results from the chemical reaction does not contain a portion, or a significant portion, of the reactant (an element or group within the reactant) and therefore the reactant is not a precursor.

As used herein, a “substrate” refers to an underlying material or materials that may be used to form, or upon which, a device, a circuit, a material, or a material layer may be formed. The substrate may be continuous or non-continuous; rigid or flexible; solid or porous; and combinations thereof. The substrate may be in any form, such as, for example, a powder, a sheet, a plate, or a workpiece. Substrates in the form of a sheet may extend beyond the bounds of a process/reaction chamber where a deposition process occurs and, in some cases, move through the chamber such that the process continues until the end of the substrate is reached. Substrates in the form of a plate may include wafers in various shapes and sizes. Substrates may be made from semiconductor materials, including, for example, silicon, silicon germanium, silicon oxide, gallium arsenide, gallium nitride, and silicon carbide. A substrate can include one or more layers overlying a bulk material, for example, the substrate may include nitrides (e.g., TiN), oxides, insulating materials, dielectric materials, conductive materials, metals, such as tungsten, ruthenium, molybdenum, cobalt, aluminum, or copper, or other metallic materials, crystalline materials, epitaxial, heteroepitaxial, and/or single crystal materials. The substrate can include various topologies, such as, for example, gaps, recesses, lines, trenches, vias, holes, or spaces between elevated portions, such as fins, and the like formed within or on at least a portion of a layer of the substrate. Although the term “substrate” may be used in singular form throughout the disclosure, it should be understood that the term “substrate” can include one or more substrates unless explicitly stated otherwise.

Articles “a” or “an” refer to a species or a genus including multiple species, depending on the context. As such, the terms “a/an”, “one or more”, and “at least one” can be used interchangeably herein.

The terms “comprising”, “including”, and “having” are open ended and do not exclude the presence of other elements or components, unless the context clearly indicates otherwise. “Comprising”, “including”, and “having” can be used interchangeably and include the meaning of “consisting of”. The phrase “consisting of”, however, indicates that no other features or components are present other than those mentioned, unless the context clearly indicates otherwise.

The term “about” as applied to a value generally refers to a range of numbers that is considered to be equivalent to the recited value (e.g., having the same function or result). In some instances, the term “about” may include numbers that are rounded to the nearest significant figure.

The term “essentially” as applied to a film forming composition, a method, a system, or a structure generally means that the additional components do not substantially modify the properties, characteristics, and/or function of the film forming composition, the method, the system, or the structure.

The term “substantially” as applied to a film forming composition, a method, a system, or a structure generally refers to a proportion of a value, a property, a characteristic, or the like, or conversely a lack thereof, that is at least about 70%, or at least about 80%, or at least about 90%, or at least about 95%, or at least about 97%, or at least about 98%, or at least about 99%, or at least about 99.5%, or at least about 99.9%, or more, or any proportion between about 70% and about 100%. In some embodiments, the term “substantially” means a proportion of about 90%, or about 95%, or about 97%, or about 98%, or about 99%, or about 99.5%, or about 99.9%.

The terms “on” or “over” may be used to describe a relative location relationship. For example, an element, a film, or a layer may be directly positioned on or over and physically contacting at least a portion of another element, film, or layer; or, alternatively, an element, a film, or a layer may be on or over another element, film or layer but have one or more interposed elements, films, or layers therebetween. Therefore, unless the term “directly” is separately used, the terms “on” or “over” will be construed to be a relative concept. Similar to this, it will be understood that the terms “under”, “underlying”, or “below” describe a relative location relationship and should be construed to be relative concepts.

The terms “at least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C”, and “A, B, and/or C” means A alone, B alone, C alone, A and B together, A and C together, B and C together, or A, B, and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Z₁).

It should be understood that every numerical range given throughout this disclosure is deemed to include the upper and the lower end points, and each and every narrower numerical range that falls within such broader numerical range, as if such narrower numerical ranges were all expressly written herein. By way of example, the phrase “from about 2 to about 4” or “from 2 to 4” includes 2 and 4 and the whole number and/or integer ranges from about 2 to about 3, from about 3 to about 4, and each possible range based on real (e.g., irrational and/or rational) numbers, such as from about 2.1 to about 3.9, from about 2.1 to about 3.4, and so on.

The standard abbreviations of the elements in the periodic table are used herein.

In certain places throughout the disclosure, a chemical compound, a functional group of a chemical compound, or a substituent or ligand may be referred to by a chemical name (e.g., an IUPAC name or a common name), a chemical formula which may be abbreviated, or both. In cases where there is a conflict between the chemical name and/or the chemical formula, and the identity of the chemical compound, the functional group, or the substituent or ligand cannot be unambiguously ascertained by one of skill in the art, then the chemical formula shall prevail.

In this disclosure, any defined meanings do not necessarily exclude ordinary and customary meanings, in some embodiments.

Disclosed herein is a film forming composition that is configured for forming a low-k material film. The film forming composition comprises a silicon precursor that has a Si—O—Si, a Si—NH—Si, or a Si—CH₂—Si bonding structure and one or more methyl groups bonded to the Si atom(s). Without wishing to be bound by a particular theory, it is hypothesized that the presence of a Si—O—Si, a Si—NH—Si, or a Si—CH₂—Si bonding structure and the Si—CH₃ bond(s) in the silicon precursor leads to high levels of carbon incorporation into the resulting low-k material film and therefore reduces the propensity for plasma induced damage. Also disclosed herein is a vapor deposition method and system for forming a low-k material film using said film forming composition.

An aspect of the present disclosure relates to a film forming composition that is configured for forming a low-k material film. The film forming composition comprises a silicon precursor that has a structure that comprises a Si—O—Si, a Si—NH—Si, or a Si—CH₂—Si bonding structure, and one or more methyl groups bonded to the Si atom(s). More specifically, the film forming composition comprises a silicon precursor that has a structure according to a general Formula (1):

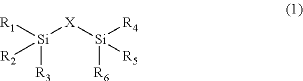

wherein, X is selected from an O atom, an NH group, and a CH₂ group; and R¹, R², R³, R⁴, R⁵, and R⁶ are each a substituent group that is independently selected from a hydrogen atom, a C₁-C₆ alkyl group, a C₂-C₆ alkenyl group, and a C₁-C₆ alkoxy group with the proviso that at least one of R¹, R², R³, R⁴, R⁵, and R⁶ is a methyl group (CH₃). Preferably, at least two of R¹, R², R³, R⁴, R⁵, and R⁶ are methyl groups. In some instances, preferably at least four of R¹, R², R³, R⁴, R⁵, and R⁶ are methyl groups.

With regard to general Formula (1): A C₁-C₆ alkyl group may have a linear or branched structure and may be selected from methyl (CH₃), ethyl (C₂H₅), propyl (C₃H₇), butyl (C₄H₉), pentyl (C₅H₁₁), and hexyl (C₆H₁₃), typically the C₁-C₆ alkyl group is selected from methyl (CH₃) and ethyl (C₂H₅). A C₂-C₆ alkenyl group may have a linear or branched structure and may be selected from vinyl (C₂H₃), methyl vinyl (C₃H₅), dimethyl vinyl (C₄H₇), ethyl vinyl (C₄H₇), and other C₄-C₆ alkenyl groups, typically the C₂-C₆ alkenyl group is a vinyl group. A C₁-C₆ alkoxy group may have a linear or branched structure and may be selected from methoxy (CH₃O), ethoxy (C₂H₅O), propoxy (C₃H₇O), butoxy (C₄H₉O), pentoxy (C₅H₁₁O), and hexoxy (C₆H₁₃O), typically the C₁-C₆ alkoxy group is selected from methoxy (CH₃O) and ethoxy (C₂H₅O).

In some embodiments, the silicon precursor has a structure according to general Formula (1), wherein X is selected from an O atom, an NH group, and a CH₂ group; R¹ is selected from a C₂-C₆ alkenyl group and a C₁-C₆ alkoxy group; and R², R³, R⁴, R⁵, and R⁶ are each independently selected from a hydrogen atom and a C₁-C₆ alkyl group with the proviso that at least one of R², R³, R⁴, R⁵, and R⁶ is a methyl group (CH₃). Preferably at least two of R², R³, R⁴, R⁵, and R⁶ are methyl groups. Preferably, at least R² and R³ are methyl groups. Preferably, at least R², R³, R⁵, and R⁶ are methyl groups. In some preferred embodiments, a silicon atom of the silicon precursor is beneficially bonded to two methyl groups.

In some embodiments, the silicon precursor has a structure according to general Formula (1), wherein X is selected from an O atom, an NH group, and a CH₂ group; R¹ and R⁴ are each selected from a C₂-C₆ alkenyl group and a C₁-C₆ alkoxy group; and R², R³, R⁵, and R⁶ are each independently selected from a hydrogen atom and a C₁-C₆ alkyl group with the proviso that at least two of R², R³, R⁵, and R⁶ are methyl groups (CH₃). Preferably, R² and R³ or R⁵ and R⁶ are methyl groups. In some embodiments, R², R³, R⁵, and R⁶ are methyl groups. In some preferred embodiments, a silicon atom of the silicon precursor is beneficially bonded to two methyl groups.

In some embodiments, the silicon precursor has a structure according to general Formula (1), wherein X is selected from an O atom, an NH group, and a CH₂ group; and R¹, R², R³, R⁴, R⁵, and R⁶ are each independently selected from a hydrogen atom and a C₁-C₆ alkyl group with the proviso that at least one of R¹, R², R³, R⁴, R⁵, and R⁶ is a methyl group (CH₃). Preferably at least two of R¹, R², R³, R⁴, R⁵, and R⁶ are methyl groups. In some embodiments, at least four of R¹, R², R³, R⁴, R⁵, and R⁶ are methyl groups. In some preferred embodiments, a silicon atom of the silicon precursor is beneficially bonded to two methyl groups.

In some embodiments, the X group of the silicon precursor is an oxygen atom; hence the silicon precursor comprises a Si—O—Si bonding structure.

In some of these embodiments, the silicon precursor further comprises at least one C₂-C₆ alkenyl group, preferably a vinyl group. Suitable silicon precursors comprising a Si—O—Si bonding structure and at least one C₂-C₆ alkenyl group include, but are not limited to, 1,3-dimethyl-1,3-divinyldisiloxane (CH₂CHSiH(CH₃)OSiH(CH₃)CHCH₂), 1,1,3,3-tetramethyl-1-vinyldisiloxane (CH₂CHSi(CH₃)₂OSiH(CH₃)CH₃), 1,1,3,3,3-pentamethyl-1-vinyldisiloxane (CH₂CHSi(CH₃)₂OSi(CH₃)₂CH₃), and 1,1,3,3-tetramethyl-1,3-divinyldisiloxane (CH₂CHSi(CH₃)₂OSi(CH₃)₂CHCH₂). In some other of these embodiments, the silicon precursor further comprises at least one C₁-C₆ alkoxy group, preferably a methoxy group or an ethoxy group. Suitable silicon precursors comprising a Si—O—Si bonding structure and at least one C₁-C₆ alkoxy group include, but are not limited to, 4-methyl-1,1,3,3-tetramethyldisiloxane (CH₃SiH(CH₃)OSi(CH₃)₂OCH₃), 4-ethyl-1,1,3,3-tetramethyldisiloxane (CH₃SiH(CH₃)OSi(CH₃)₂OCH₂CH₃), 4-methyl-1,1,1,3,3-pentamethyldisiloxane (CH₃Si(CH₃)₂OSi(CH₃)₂OCH₃), 4-ethyl-1,1,1,3,3-pentamethyldisiloxane (CH₃Si(CH₃)₂OSi(CH₃)₂OCH₂CH₃), 1,3-dimethoxy-1,3-dimethyldisiloxane (CH₃OSiH(CH₃)₂OSiH(CH₃)OCH₃), 1,3-diethoxy-1,3-dimethyldisiloxane (CH₃CH₂OSiH(CH₃)₂OSiH(CH₃)OCH₂CH₃), 1,3-dimethoxy-1,1,3,3-tetramethyldisiloxane (CH₃OSi(CH₃)₂OSi(CH₃)₂OCH₃), and 1,3-diethoxy-1,1,3,3-tetramethyldisiloxane (CH₃CH₂OSi(CH₃)₂OSi(CH₃)₂OCH₂CH₃). In yet some other of these embodiments, the silicon precursor further comprises at least one C₂-C₆ alkenyl group and at least one C₁-C₆ alkoxy group. Suitable silicon precursors comprising a Si—O—Si bonding structure and at least one C₂-C₆ alkenyl group and at least one C₁-C₆ alkoxy group include, but are not limited to, 1,3-divinyl-1,3-dimethyl-1,3-dimethoxydisiloxane (CH₂CHSi(CH₃)(OCH₃)OSi(CH₃)(OCH₃)CHCH₂). In yet some other of these embodiments, the silicon precursor further comprises four or more methyl groups. Suitable silicon precursors comprising a Si—O—Si bonding structure and four or more methyl groups include, but are not limited to, 1,1,3,3-tetramethyldisiloxane (CH₃SiH(CH₃)OSiH(CH₃)CH₃), and hexamethyldisiloxane (CH₃Si(CH₃)₂OSi(CH₃)₂CH₃).

In some embodiments, the X group of the silicon precursor is an NH group; hence the silicon precursor comprises a Si—NH—Si bonding structure.

In some of these embodiments, the silicon precursor further comprises at least one C₂-C₆ alkenyl group, preferably a vinyl group. Suitable silicon precursors comprising a Si—NH—Si bonding structure and at least one C₂-C₆ alkenyl group include, but are not limited to, 1,3-dimethyl-1-vinyldisilazane (CH₂CHSiH(CH₃)NHSiH₂CH₃), 1,1,3,3-tetramethyl-1-vinyldisilazane (CH₂CHSi(CH₃)₂NHSiH(CH₃)CH₃), 1,1,3,3,3-pentamethyl-1-vinyldisilazane (CH₂CHSi(CH₃)₂NHSi(CH₃)₂CH₃), 1,3-dimethyl-1,3-divinyldisilazane (CH₂CHSiH(CH₃)NHSiH(CH₃)CHCH₂), and 1,1,3,3-tetramethyl-1,3-divinyldisilazane (CH₂CHSi(CH₃)₂NHSi(CH₃)₂CHCH₂). In some other of these embodiments, the silicon precursor further comprises four or more methyl groups. Suitable silicon precursors comprising a Si—NH—Si bonding structure and four or more methyl groups include, but are not limited to, 1,1,3,3-tetramethyldisilazane (CH₃SiH(CH₃)NHSiH(CH₃)CH₃), and hexamethyldisilazane (CH₃Si(CH₃)₂NHSi(CH₃)₂CH₃).

In some embodiments, the X group of the silicon precursor is a CH₂ group; hence the silicon precursor comprises a Si—CH₂—Si bonding structure.

In some of these embodiments, the silicon precursor further comprises at least one C₂-C₆ alkenyl group, preferably a vinyl group. Suitable silicon precursors comprising a Si—CH₂—Si bonding structure and at least one C₂-C₆ alkenyl group include, but are not limited to, 4-methyl-2,4-disilahex-5-ene (CH₃SiH₂CH₂SiH(CH₃)CHCH₂), 2,4,4-trimethyl-2,4-disilahex-5-ene (CH₃SiH(CH₃)CH₂Si(CH₃)₂CHCH₂), 2,2,4,4-tetramethyl-2,4-disilahex-5-ene (CH₃Si(CH₃)₂CH₂Si(CH₃)₂CHCH₂), bis(methylvinylsilyl)methane (CH₂CHSiH(CH₃)CH₂SiH(CH₃)CHCH₂), and bis(dimethylvinylsilyl)methane (CH₂CHSi(CH₃)₂CH₂Si(CH₃)₂CHCH₂). In some other of these embodiments, the silicon precursor further comprises at least one C₁-C₆ alkoxy group, preferably a methoxy group or an ethoxy group. Suitable silicon precursors comprising a Si—CH₂—Si bonding structure and at least one C₁-C₆ alkoxy group include, but are not limited to, 2,4,4-trimethyl-5-oxa-2,4-disilahexane (CH₃SiH(CH₃)CH₂Si(CH₃)₂OCH₃), 2,4,4-trimethyl-5-oxa-2,4-disilaheptane (CH₃SiH(CH₃)CH₂Si(CH₃)₂OCH₂CH₃), 2,2,4,4-tetramethyl-5-oxa-2,4-disilahexane (CH₃Si(CH₃)₂CH₂Si(CH₃)₂OCH₃), 2,2,4,4-tetramethyl-5-oxa-2,4-disilaheptane (CH₃Si(CH₃)₂CH₂Si(CH₃)₂OCH₂CH₃), 3,3,5,5-tetramethyl-2,6-dioxa-3,5-disilaheptane (CH₃OSi(CH₃)₂CH₂Si(CH₃)₂OCH₃), 3,3,5,5-tetramethyl-2,6-dioxa-3,5-disilanonane (CH₃CH₂OSi(CH₃)₂CH₂Si(CH₃)₂OCH₂CH₃), 3,5-dimethoxy-3,5-dimethyl-2,6-dioxa-3,5-disilaheptane (CH₃OSi(CH₃)(OCH₃)CH₂Si(CH₃)(OCH₃)OCH₃), and ((dimethoxymethylsilyl)methyl)trimethylsilane (CH₃O)₂CSiH₂CH₂Si(CH₃)₂CH₃). In yet some other of these embodiments, the silicon precursor further comprises at least one C₂-C₆ alkenyl group and at least one C₁-C₆ alkoxy group. Suitable silicon precursors comprising a Si—CH₂—Si bonding structure and at least one C₂-C₆ alkenyl group and at least one C₁-C₆ alkoxy group include, but are not limited to, ((dimethoxymethylsilyl)methyl) ethenyldimethylsilane (CH₂CHSi(CH₃)₂CH₂Si(OCH₃)₂CH₃).

The film forming compositions disclosed herein are configured for forming a low-k material film. In this regard, the purity of the film forming composition e.g., of the silicon precursor, should be sufficient for forming a low-k material film that has good electrical and mechanical properties. Impurities in the film forming composition may end up in the resulting low-k material film, leading to poor film properties. Impurities in the film forming composition may be due to unreacted reactants, reaction byproducts, catalysts, and/or solvents from the synthesis method, and/or from decomposition products. In some embodiments, a purity of the film forming composition, e.g., of the silicon precursor, is at least about 90 wt. %, or at least about 95 wt. %, or at least about 97 wt. %, or at least about 98 wt. %, or at least about 99 wt. %, or at least about 99.5 wt. %, or at least about 99.7 wt. %, or at least about 99.9 wt. %, or even at least about 99.99 wt. %, or even at least about 99.999 wt. %. High purity film forming compositions may be preferred for chemical vapor deposition applications; however, very high purity film forming compositions may unnecessarily increase the cost of the deposition process and hence the cost of the resulting layer. Thus, it is desirable for the film forming composition to have a suitable purity for the application without unnecessarily increasing the cost. In some embodiments, the film forming composition has a purity that is between about 95 wt. % and about 99.9 wt. %, or between about 97 wt. % and about 99.9 wt. %, or between about 98 wt. % and about 99.9 wt. %, or between about 99 wt. % and about 99.9 wt %, or between about 97 wt. % and about 99.5 wt. %, or between about 97 wt. % and about 99 wt. %. In other embodiments, higher purity film forming compositions are required, and the film forming composition has a purity that is between about 99.9 wt. % and about 99.99 wt. %.

In some embodiments, an amount of silicon containing impurities in the film forming composition is no more than about 10 wt %, or no more than about 5 wt %, or no more than about 4 wt %, or no more than about 3 wt %, or no more than about 2 wt %, or no more than about 1 wt %, or no more than about 0.5 wt %, or no more than about 0.1 wt %, or no more than about 100 ppm, or no more than about 10 ppm. In some embodiments, an amount of halogen containing impurities in the film forming composition is no more than about 5 wt %, or no more than about 4 wt %, or no more than about 3 wt %, or no more than about 2 wt %, or no more than about 1 wt %, or no more than about 0.5 wt %, or no more than about 0.1 wt %, or no more than about 100 ppm, or no more than about 10 ppm. In some embodiments, an amount of metal impurities in the film forming composition is no more than about 1 wt %, or no more than about 0.1 wt %, or no more than about 100 ppm, or no more than about 10 ppm, or no more than about 1 ppm, or no more than about 100 ppb, or no more than about 10 ppb.

Any features of any embodiment of the aspect related to the film forming composition may be independently applied, as appropriate, as correspondingly described for any embodiment of any of the other aspects of the present invention.

Another aspect of the present disclosure is related to a precursor delivery vessel comprising the film forming composition described in any of the above related paragraphs. The precursor delivery vessel is configured to store the film forming composition and to provide a flow of the film forming composition from the precursor delivery vessel to an external environment, for example, to a substrate processing apparatus for forming a low-k material film. In some embodiments, the precursor delivery vessel is a liquid delivery vessel; hence the vessel is configured to deliver a liquid flow of the film forming composition from the vessel to an external environment for vaporization. In other embodiments, the precursor delivery vessel is a vapor vessel; hence the vessel is configured to deliver a vapor flow of the film forming composition from the vessel to an external environment. The configuration of the precursor delivery vessel may vary in different embodiments of the disclosure, depending upon the application in question. However, the precursor delivery vessel is generally formed from a material that is non-reactive to the film forming composition and, in some embodiments, may also be compliant with U.S. Department of Transportation (DOT) regulations, such as 49 C.F.R. § 178 (2021). In some embodiments, the precursor delivery vessel is formed from stainless steel (e.g., 316, 316L, 304, or 304L alloys). The precursor delivery vessel generally comprises an outer wall that encloses a cavity for storing the film forming composition and an outlet for allowing a flow of the film forming composition to exit the cavity. The outlet is seated in the outer wall of the precursor delivery vessel and is in communication with the cavity of the precursor delivery vessel and has at least one valve positioned thereon to fluidly couple or decouple the cavity to the outside environment.

In some embodiments, the precursor delivery vessel comprises one or more other fluid inlets or outlets, in addition to the outlet. For example, the precursor delivery vessel may comprise a fluid inlet that is seated in the outer wall of the precursor delivery vessel and is in communication with the cavity of the precursor delivery vessel and having at least one valve positioned thereon for filling the precursor delivery vessel with the film forming composition. Additionally, or alternatively, the precursor delivery vessel may comprise a fluid inlet that is seated in the outer wall of the precursor delivery vessel and is in communication with the cavity of the precursor delivery vessel and having at least one valve positioned thereon for flowing a carrier gas into the cavity of the vessel, either over the surface of the film forming composition and/or through the film forming composition in the case of vapor delivery, or for pressurizing the cavity of the vessel in the case of liquid delivery to help facilitate the flow of the film forming composition from the precursor delivery vessel. Some or all of the one or more valves provided on the various inlets and outlets may be rated for high temperature (e.g., typically up to 100° C., or up to 150° C., or up to 200° C., or up to 250° C.) to withstand the temperatures that may be required to provide sufficient vapor pressure and/or prevent condensation of the film forming composition within the valves and other components, and/or to obtain a sufficient viscosity to facilitate flow from the precursor delivery vessel.

In some embodiments, the precursor delivery vessel further comprises one or more probe members, that may comprise one or more temperature sensors, and/or one or more pressure sensors, and/or one or more level sensors. A variety of level sensors for measuring the amount of the film forming composition within the cavity of the precursor delivery vessel are known in the art, including, but not limited to, capacitive-based sensors, conductivity-based sensors, float switch level sensors, tuning fork sensors, and ultrasonic sensors. The various design features described above may be combined, as appropriate, to optimize the flow of the film forming composition from the precursor delivery vessel.

Any features of any embodiment of the aspect related to the precursor delivery vessel may be independently applied, as appropriate, as correspondingly described for any embodiment of any of the other aspects of the present invention.

Another aspect of the present disclosure relates to methods for forming a low-k material film on the surface of a substrate using a chemical vapor deposition (CVD) method and using the film forming compositions described in any of the above related paragraphs. Suitable CVD methods include plasma-enhanced CVD (PE-CVD), which may further include continuous and cyclic CVD methods. The methods generally comprise providing a substrate in a reaction chamber, introducing a vapor of the film forming composition into the reaction chamber, forming a plasma in the reaction chamber, and depositing a film of a low-k material on the surface of the substrate under CVD conditions. Generally, and without wishing to be bound by a particular mechanism, silicon precursor molecules may be broken down in the gas phase near the surface of the substrate and/or on the surface of the substrate, which results in the formation of a low-k material film on the surface of the substrate.

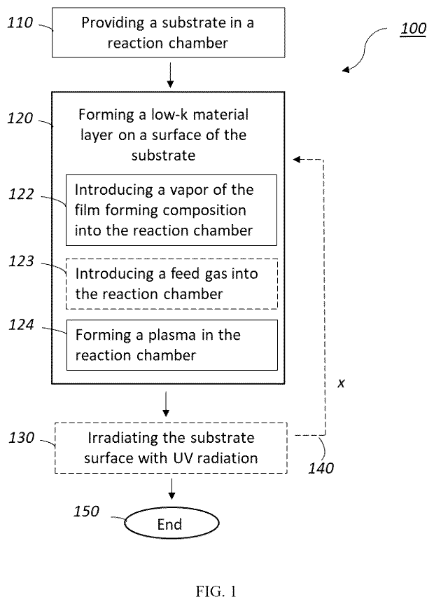

FIG. 1 is a process flow diagram of a PE-CVD method 100 for forming a low-k material film on the surface of a substrate in accordance with an exemplary embodiment of the disclosure. The method 100 comprises providing a substrate in a reaction chamber 110 and forming a low-k material film on a surface of the substrate 120 by introducing a vapor flow of the film forming composition into the reaction chamber 122, optionally introducing a feed gas into the reaction chamber 123, and forming a plasma in the reaction chamber 124. The steps of introducing the vapor flow of the film forming composition into the reaction chamber 122, optionally introducing the feed gas into the reaction chamber 123, and forming a plasma in the reaction chamber 124 overlap, at least in part. Once a desired film thickness and/or uniformity has been reached, the vapor flow of the film forming composition into the reaction chamber may be ceased and the plasma deactivated. The low-k material film may then be optionally irradiated with UV radiation 130 to increase the elastic modulus of the film, among other things. The process may optionally be repeated 140 one or more (x) times to increase the thickness and/or the uniformity of the low-k material film, and/or the process may be terminated 150.

In the disclosed methods for forming a low-k material film, a substrate is provided in a reaction chamber 110 where the deposition conditions can be controlled. The substrate is not particularly limited and is discussed above. The reaction chamber may be a component of a vapor deposition assembly, which in turn may be a component of a substrate processing apparatus. The reaction chamber may be one of a multitude of chambers in a cluster tool in which different processes are performed in the various chambers to form an integrated circuit.

In some embodiments, the step of providing the substrate in a reaction chamber 110 further comprises maintaining a temperature of the substrate and/or a temperature of the reaction chamber at a set temperature. For instance, the substrate may be maintained at an elevated temperature (i.e., above room temperature). In some embodiments, the substrate may be maintained at a first temperature during the deposition process and a second temperature during other process steps. The temperature of the substrate may be optimized to tune or maximize the deposition process on the substrate surface. In some embodiments, the method further comprises heating the substrate to a temperature of at least about 40° C. and no more than about 500° C. In some embodiments, the method comprises maintaining the substrate temperature from about 40° C. to about 500° C., typically from about 100° C. to about 450° C., or from about 100° C. to about 400° C., or from about 100° C. to about 350° C., or from about 100° C. to about 325° C., or from about 100° C. to about 300° C., or from about 100° C. to about 275° C., or from about 100° C. to about 250° C. In some embodiments, the method further comprises heating the substrate to a temperature of less than about 450° C., or less than about 425° C., or less than about 400° C., or less than about 375° C., or less than about 350° C., or less than about 325° C., or less than about 300° C., or less than about 275° C., or less than about 250° C., or less than about 200° C.

In some embodiments, the step of providing a substrate in a reaction chamber 110 further comprises controlling a pressure within the reaction chamber. In some embodiments, the reaction chamber may be maintained at a first pressure during a first deposition process and a second pressure during other process steps. The pressure within the reaction chamber may be between about 1 mTorr and about 760 Torr, typically between about 0.5 Torr and about 100 Torr, such as about 10 Torr, or about 15 Torr, or about 20 Torr, or about 30 Torr, or about 40 Torr, or about 50 Torr. In some embodiments, a pressure within the reaction chamber during the deposition process is less than about 100 Torr, or a pressure within the reaction chamber during the deposition process is between about 0.5 Torr and about 100 Torr, or between about 1 Torr and about 50 Torr, or between about 1 Torr and about 20 Torr.

The step of introducing the film forming composition into the reaction chamber 122 comprises flowing a vapor flow of the film forming composition from a precursor delivery vessel that is fluidly coupled to the reaction chamber. The film forming composition may be provided in liquid form from a precursor delivery vessel and vaporized upstream of the reaction chamber so that a vapor flow of the film forming composition is introduced into the reaction chamber. Alternatively, the film forming composition may be provided in a vapor form from the precursor delivery vessel. In either case, the vapor of the film forming composition may optionally be entrained in a flow of a carrier gas or a dilution gas (e.g., N₂ and/or a noble gas such as helium (He) and argon (Ar)) and introduced into the reaction chamber. The flow rate of the film forming composition into the reaction chamber may be less than about 1000 sccm, or less than about 500 sccm, or less than about 400 sccm, or less than about 300 sccm, or less than about 200 sccm, or less than about 100 sccm, or less than about 50 sccm. The flow rate may be, for example, from about 1 sccm to about 500 sccm, such as about 50 sccm to about 500 sccm, or about 100 sccm to about 200 sccm. The flow rate may vary in different embodiments of the disclosure according to the specific silicon precursor utilized, the configuration of the reaction chamber, and other process parameters (e.g., temperature, pressure, substrate, plasma conditions, etc.), which may independently be selected to optimize the deposition according to the application in question.

The step of forming a plasma in the reaction chamber 124 generally comprises applying an externally imposed electric or magnetic field to ionize and/or energize a gas or a mixture of gases either within the reaction chamber or upstream of the reaction chamber. The gas mixture may comprise the silicon precursor in addition to a feed gas for forming the plasma. Hence, the method may further comprise introducing a feed gas into the reaction chamber 123 and forming the plasma in the reaction chamber.

In some embodiments, the ratio of the silicon precursor to the feed gas may be from 5:1 to 1:40, or from 5:1 to 1:30, or from 5:1 to 1:20. The ratio may be a concentration ratio or a flow rate ratio.

In some embodiments, the plasma is generated from a feed gas that comprises an oxygen-containing gas. Such plasma contains oxygen plasma species, which may comprise one or more of ionic species, radical species, and excited species. In some of these embodiments, the ratio of the silicon precursor to the oxygen-containing gas may be from 100:1 to 1:1, or from 20:1 to 1:1, or from 10:1 to 1:1, or from 5:1 to 1:1, or from 2:1 to 1:1. Preferably the ratio of the silicon precursor to the oxygen-containing gas is from 2:1 to 1:1. The ratio may be a concentration ratio or a flow rate ratio.

Additionally, or alternatively, in some embodiments, the plasma is generated from a feed gas that comprises an inert gas, such as nitrogen and/or a noble gas. In some embodiments, the plasma is generated from Ar, He, or a mixture thereof.

In some embodiments, the step of forming a plasma in the reaction chamber 124 further comprises introducing an oxygen-containing gas into the reaction chamber. In some embodiments, the plasma is generated from a feed gas that comprises an oxygen-containing gas such as, for example, nitrous oxide (N₂O), nitrogen dioxide (NO₂), nitric oxide (NO), oxygen (O₂), ozone (O₃), carbon dioxide (CO₂), carbon monoxide (CO), and mixtures thereof.

The flow rate of the oxygen-containing gas into the reaction chamber (e.g., into the plasma unit) may be less than about 1000 sccm, or less than about 500 sccm, or less than about 400 sccm, or less than about 300 sccm, or less than about 200 sccm, or less than about 100 sccm, or less than about 50 sccm. The flow rate may be, for example for N₂O and/or O₂, from about 1 sccm to about 1000 sccm, typically about 1 sccm to about 400 sccm.

In some embodiments, the oxygen-containing gas comprises N₂O. In some of these embodiments, the oxygen-containing gas consists essentially or consists of N₂O. In some of these embodiments, the oxygen-containing gas comprises a mixture of N₂O and O₂, wherein a ratio of N₂O to O₂ is between 20:1 and 2:1, preferably between 10:1 and 3:1. The ratio may be a concentration ratio or a flow rate ratio. Use of N₂O as the reactive gas leads to O radicals in the plasma (e.g., N₂O+e⁻ à N₂+O). When O₂ is used as the reactive gas, O₂⁺ ions are formed in addition to O radicals (e.g., O₂+e⁻ à O₂⁺+2e⁻ and O₂+e⁻ à 2O+e⁻). While not wishing to be bound by a particular theory, use of N₂O as the oxygen-containing gas may beneficially provide a softer oxidation due to the high concentration of O radicals in the plasma, thereby mitigating or reducing carbon loss from the film. Hence, the Si—CH₃ bonds in the film may be preserved. Further, the softer oxidation may reduce the hydrogen content of the film without significantly increasing the oxygen content of the film. Adding a small amount of O₂, along with N₂O, to the reactive gas may increase the number of Si—O—Si bonds in the film while not significantly increasing carbon loss. The ratio of N₂O to O₂ may be selected to optimize one or more of the PID resistance, the elastic modulus, and the k-value of the film.

Additionally, or alternatively, in some embodiments, the feed gas comprises nitrogen (N₂) and/or a noble gas. In some embodiments, the step of forming a plasma in the reaction chamber 124 further comprises introducing nitrogen (N₂) and/or a noble gas into the reaction chamber (e.g., into the plasma unit). The flow rate of the feed gas into the reaction chamber (e.g., into the plasma unit) may be less than about 5000 sccm, or less than about 4000 sccm, or less than about 3000 sccm, or less than about 2000 sccm, or less than about 1000 sccm. The flow rate may be, for example, from about 1 sccm to about 5000 sccm, typically about 1 sccm to about 2000 sccm.

In some embodiments, the plasma is generated from a noble gas. Use of a noble gas may help in the formation and stabilization of the plasma. The noble gas may be selected from a group consisting of helium (He), neon (Ne), argon (Ar), krypton (Kr), xenon (Xe), and mixtures thereof. In some preferred embodiments, the feed gas comprises Ar. While not wishing to be bound by a particular theory, Ar has a lower first ionization energy and a greater number of available energy states, compared with He which is commonly used. Hence, the use of Ar, instead of He, may enable higher plasma density with a lower average electron temperature. The high plasma density may beneficially enable higher deposition rates, and the lower electron temperature may increase the stability of the plasma near the edge of the electrode. In other embodiments, the feed gas comprises a mixture of Ar and He. While not wishing to be bound by a particular theory, the coflow of Ar and He, may increase the plasma stability while increasing the plasma process window.

In some embodiments, the plasma is generated from a noble gas and an oxygen-containing gas. In some embodiments, the feed gas comprises a mixture of N₂O and Ar, or a mixture of N₂O and He, or a mixture of N₂O, Ar, and He. In some of these embodiments, the feed gas further comprises O₂. A ratio of N₂O to O₂ may be between 20:1 and 2:1, preferably between 10:1 and 3:1. The ratio may be a concentration ratio or a flow rate ratio. The composition of the feed gas may be selected to optimize one or more of the PID thickness, the elastic modulus, the k-value of the film, and the growth rate of the film.

Plasma generation schemes and geometries, include, but are not limited to, capacitively coupled plasmas (CCPs), inductively coupled plasmas (ICPs), and RF-hollow cathode (HC) plasmas, which differ in their production of excited and reactive species and, as a result, can provide very different fluxes of the various species. In some embodiments, the plasma comprises a capacitively coupled plasma.

The RF power and the frequency for generating the plasma can be varied in different embodiments of the disclosure. In some embodiments, the RF power for generating the plasma is maintained at about 5000 W or less, typically at least about 10 W and no more than about 2000 W, or at least about 20 W and no more than about 1000 W, or at least about 20 W and no more than about 500 W. Further, in some embodiments, the RF power may have a frequency of less than 100 MHz, typically at least about 100 kHz to no more than 100 MHz. The RF power may, in some embodiments, have a frequency of 400 kHz, 430 kHz, 2 MHz, 13.56 MHz, 27 MHz, and 60 MHz. In some embodiments, a combination of a high frequency RF power and a low-frequency RF power is utilized. The low-frequency RF power may be from 1% to 50% of the high-frequency RF power, including 1%, 5%, 10%, 15%, 20%, 30%, 40%, and any range of values between any two numbers of the foregoing. The low-frequency RF power may have a frequency of 100 kHz to 2 MHz, such as 400 kHz or 430 kHz. The high-frequency RF power may have a frequency of 2 MHz to 100 MHz, such as 13.56 MHz, 27 MHz, and 60 MHz; in some embodiments the frequency is 20 MHz or higher. In an embodiment, the total RF power may be 400 W or higher, such as 450 W, 500 W, 750 W, 1000 W, 2000 W, 3000 W, 4000 W, 5000 W and any range of values between any two numbers of the foregoing. In some of these embodiments, low-frequency RF power is less than 1000 W, while the high-frequency power is between 10 W and 5000 W.

Once a desired film thickness and/or uniformity has been reached, the vapor flow of the film forming composition into the reaction chamber may be ceased and the plasma deactivated. The low-k material film may then be optionally post processed by irradiating the substrate comprising the low-k material film with UV radiation 130 to increase the elastic modulus of the film, among other things. The wavelength of the UV radiation ranges from at least about 100 nm to no more than about 400 nm, typically at least about 100 nm to no more than about 280 nm, or at least about 120 nm to no more than about 240 nm (e.g., vacuum UV). The UV radiation power may be between about 1 mW/cm² to about 1000 mW/cm², typically 10 mW/cm², 50 mW/cm², 100 mW/cm², 200 mW/cm², 500 mW/cm², 1000 mW/cm² and any range of values between any two numbers of the foregoing. Irradiating the substrate comprising the low-k material film may be performed at room temperature or at an elevated temperature. Preferably the step of irradiating the substrate comprising the low-k material film may be performed at an elevated temperature of at least about 40° C. to no more than about 500° C., typically the temperature of the substrate may be maintained at the same temperature or range of temperatures that the deposition process occurs at. Irradiating the substrate comprising the low-k material film may be performed over a time period of seconds, minutes, or hours, for example 30 sec., 1 min., 5 min, 10 min., 30 min., 60 min., and values between any two numbers of the foregoing.

In some embodiments, the step of irradiating the substrate comprising the low-k material film with UV radiation occurs in the same reaction chamber as the deposition occurs. In other embodiments, the substrate comprising the low-k material film is transferred to a UV curing chamber for irradiation. Further, in some embodiments, an inert gas may be introduced into the reaction chamber or UV curing chamber during the irradiating or curing step to remove volatile products and/or reactive gases from the surface of the substrate.

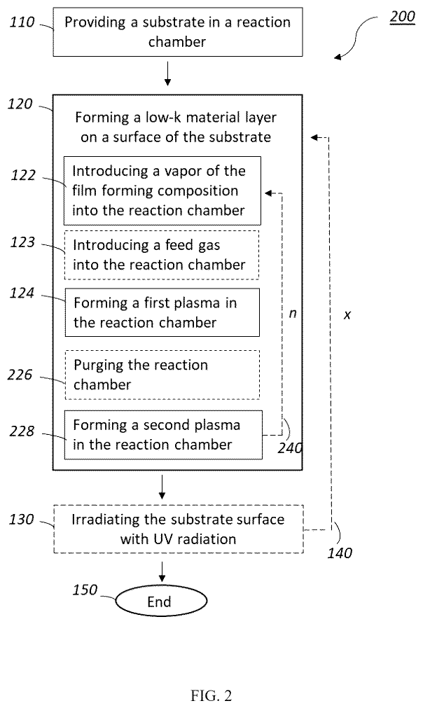

FIG. 2 shows a process flow diagram of a PE-CVD method 200 for forming a low-k material film on the surface of a substrate in accordance with another exemplary embodiment of the disclosure. The method 200 comprises providing a substrate in a reaction chamber 110 and forming a low-k material film on a surface of the substrate 120 using a deposition process comprising introducing a vapor flow of the film forming composition into the reaction chamber 122, optionally introducing a feed gas into the reaction chamber 123, and forming a first plasma in the reaction chamber 124. The steps of introducing a vapor flow of the film forming composition into the reaction chamber 122, optionally introducing a feed gas into the reaction chamber 123, and forming a first plasma in the reaction chamber 124 overlap, at least in part. Once a desired intermediate film thickness (typically <20 Å) and/or uniformity has been reached, the vapor flow of the film forming composition and the optional flow of the feed gas into the reaction chamber may be ceased and the plasma deactivated. The reaction chamber may optionally be purged 226 to remove the film forming composition, the optional feed gas, and any reactant gases and reaction by-products from the reaction chamber. Next, a second plasma is formed in the reaction chamber 228. The process steps may optionally be repeated 240 one or more n times to increase the thickness and/or uniformity of the low-k material film on the surface of the substrate. The low-k material film may then be optionally irradiated with UV radiation 130 to increase the elastic modulus of the film, among other things. The process may optionally be repeated 140 one or more (x) times to further increase the thickness and/or the uniformity of the low-k material film, and/or the process may be terminated 150. The process steps shown in FIG. 2 are described above.

Any features of any embodiment of the aspect related to the method for forming a low-k material film may be independently applied, as appropriate, as correspondingly described for any embodiment of any of the other aspects of the present invention.

Another aspect of the present disclosure relates to a system (e.g., a substrate processing apparatus) for forming a low-k material film on a surface of a substrate using the film forming compositions and CVD methods described in any of the above related paragraphs. The substrate processing apparatus may be a semiconductor processing apparatus. The substrate processing apparatus comprises at least one vapor deposition assembly that is configured for PE-CVD. The vapor deposition assembly comprises a reaction chamber, a means for housing a substrate within the reaction chamber, a source of the film forming composition, a means for introducing a vapor of the film forming composition into the reaction chamber, and a means for generating a plasma within the reaction chamber. The substrate processing apparatus may further comprise at least one UV curing assembly comprising a curing chamber, a means for housing a substrate within the curing chamber, and a means for irradiating the surface of the substrate with UV radiation. The substrate processing apparatus may comprise one or more modules for loading and unloading the substrate in the various assemblies and/or between the various assemblies. For example, the one or more modules may transfer the substrate from the vapor deposition assembly to the UV curing assembly.

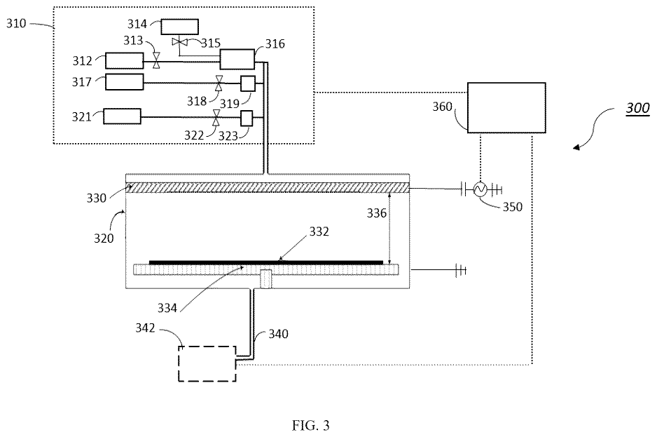

FIG. 3 shows a schematic diagram of an exemplary embodiment of a vapor deposition assembly 300 according to the present disclosure. The film forming composition and other gases are provided into a reaction chamber 320 through an injector system 310. The injector system 310 is configured to provide the film forming composition from a film forming composition source 312 (e.g., a precursor delivery vessel comprising the film forming composition) that is in fluid communication with the reaction chamber 320 via a film forming composition source valve 313. The film forming composition may be provided from the film forming composition source 312 in liquid form and vaporized in a vaporization unit 316 comprising a vaporizer and one or more mass flow controllers. A carrier gas flow may optionally be provided from a carrier gas source 314 coupled to the vaporization unit 316 via a carrier gas source valve 315. The injector system 310 may further be configured to provide a feed gas from one or more feed gas sources that are in fluid communication with the reaction chamber via one or more feed gas source valves. For instance, the injector system 310 may further be configured to provide one or more of an oxygen-containing gas from an oxygen-containing gas source 317 that is in fluid communication with the reaction chamber 320 via an oxygen-containing gas source valve 318 and an oxygen-containing gas mass flow controller 319, and an inert gas from an inert gas source 321 that is in fluid communication with the reaction chamber 320 via an inert gas source valve 322 and an inert gas mass flow controller 323. The injector system 310 may further comprise a means for heating some or all of the various components, if required, to facilitate the introduction of the film forming composition into the reaction chamber 320. The various gases flow into the reaction chamber 320 through a showerhead 330 that is positioned over a substrate 332 positioned on a susceptor 334. In some embodiments, the reaction chamber 320 further comprises one or more heating elements (not shown) that are in thermal communication with the substrate 332 and one or more thermocouples (not shown), to measure and maintain a temperature of the substrate 332 at set temperatures. Unreacted gases and gaseous reaction by-products exit the reaction chamber 320 through an exhaust line 340 that is optionally coupled to one or more vacuum pumps 342.

The vapor deposition assembly 300 further comprises a plasma unit that comprises a power generator 350 (e.g., an RF power generator or microwave power generator). In FIG. 3, a capacitively coupled plasma is formed. The power generator 350 is electrically connected to the showerhead 330, allowing for the showerhead 330 to be biased relative to the susceptor 334 to form a plasma discharge between the two. The distance between the showerhead and the susceptor, referred to as the “process gap”, 336 may be varied to optimize the plasma density near the substrate surface. Typically, the process gap is at least about 5 mm to no more than about 30 mm. The power generator may be configured to apply a combination of a high frequency RF power and a low-frequency RF power to the reaction chamber.

The deposition assembly 300 also comprises a controller 360 operably connected to the components of the injector system 310 (e.g., the film forming composition source valve 313, the optional carrier gas source valve 315, the vaporization unit 316, the oxygen-containing gas source valve 318, the oxygen-containing gas mass flow controller 319, the inert gas source valve 322, and the inert gas mass flow controller 323), the power generator 350, and other components. The controller 360 is configured and programmed to independently control (e.g., turn on and off, meter, etc.) the supply of the film forming composition, the optional carrier gas, the oxygen-containing gas, the inert gas, the power generator 350, and other components, as required, to form a low-k material film on a surface of the substrate 332. For instance, the controller 360 may be configured and programmed to perform the steps to form a low-k material film on a surface of the substrate 332 (e.g., as shown in 120 in FIG. 1 or FIG. 2 and discussed above).

As will be appreciated by one of skill in the art, other vapor deposition assembly configurations are possible. For example, although the injector system 310 and reaction chamber 320 are shown and described herein as having a specific structure and flow configuration, other flow configurations and/or other mechanisms for providing the various reactants and gases and for housing the substrate and flowing gases over the substrate may be utilized. For example, the film forming composition may be introduced into the reaction chamber from a vapor delivery vessel. In another example, the reaction chamber may be configured in a cross flow configuration. Additionally, other plasma generation configurations may be utilized. In some embodiments, a remote plasma unit that is positioned upstream of the reaction chamber may be used to generate a remote plasma. For example, a plasma may be formed upstream of the reaction chamber using an ICP unit with an RF bias being placed on the susceptor. Additionally, the vapor deposition assembly may comprise a number of other components that are not shown here.

The substrate processing apparatus may include the deposition assembly 300 and further comprise a UV curing assembly. A substrate may be transferred to the UV curing assembly after a low-k material film is deposited on the surface of the substrate in the deposition assembly 300. The UV curing assembly may comprise a curing chamber comprising a susceptor and one or more UV lamps. The one or more UV lamps typically produce radiation in the range of at least about 100 nm to no more than about 400 nm, typically at least about 100 nm to no more than about 280 nm, or at least about 120 nm to no more than about 240 nm (e.g., vacuum UV). The UV radiation power may be between about 1 mW/cm² to about 1000 mW/cm², typically 10 mW/cm², 50 mW/cm², 100 mW/cm², 200 mW/cm², 500 mW/cm², 1000 mW/cm² and any range of values between any two numbers of the foregoing. The UV curing assembly may further optionally comprise one or more heating elements that are in thermal communication with the substrate, positioned on the susceptor, and one or more thermocouples, to measure and maintain a temperature of the substrate at set temperatures. The UV curing assembly may further optionally comprise one or more gas inlets for flowing a gas (e.g., an inert gas) into the curing chamber while the substrate is irradiated.

Any features of any embodiment of the aspect related to the system for forming a low-k material film may be independently applied, as appropriate, as correspondingly described for any embodiment of any of the other aspects of the present invention.

The disclosed film forming compositions and the methods and the systems for using said film forming compositions to form a low-k material film may provide several benefits. Without wishing to be bound by a particular theory, it is hypothesized that the presence of the Si—O—Si, a Si—NH—Si, or a Si—CH₂—Si bonding structure and CH₃—Si bond(s) in the silicon precursor structure provides a low-k material film with a high carbon content and that advantageously reduces the propensity for plasma induced damage.

In some embodiments, the low-k material film comprises silicon, oxygen, and carbon. In some embodiments, the low-k material film comprises silicon oxycarbide (“SiOC”). The silicon content of the low-k material film may be at least about 10 at. % to no more than about 50 at. %, or at least about 20 at. % to no more than about 40 at. %. The oxygen content of the low-k material film may be at least about 5 at. % to no more than about 40 at. %, or at least about 10 at. % to no more than about 30 at. %. The carbon content of the low-k material film may be at least about 10 at. % to no more than about 70 at. %, or at least about 20 at. % to no more than about 60 at. %. In some embodiments, the carbon content of the low-k material film may be at least about 20 at. %, or preferably at least about 30 at. %, or more preferably at least about 40 at. %, or even at least about 50 at. %. In these embodiments, the carbon may be in the form of CH₃ groups, for example as Si—CH₃ bonds within the film. The high carbon content of the film is beneficial for reducing PID. The low-k material film may comprise other elements, in addition to silicon, oxygen, and carbon, such as for example nitrogen in some instances and hydrogen.

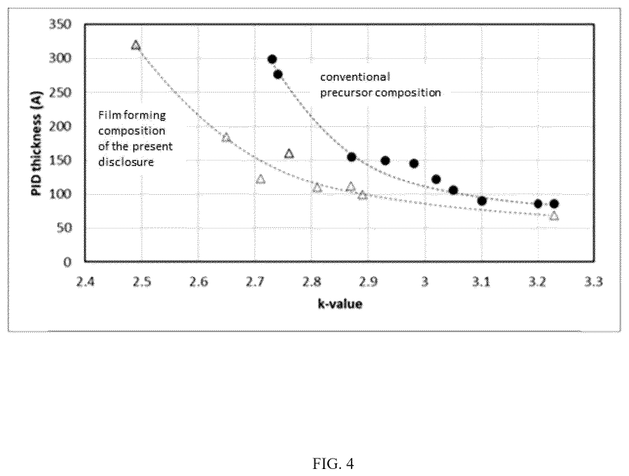

FIG. 4. illustrates a plasma induced damage layer thickness (“PID layer” thickness) versus k-value of PE-CVD deposited films using a conventional precursor composition comprising dimethyldimethoxysilane (DMDMOS) and a film forming composition according to the present disclosure comprising a siloxane precursor. The plasma induced damage thickness increases as the k-value decreases. This is because the increase in the porosity in the film allows etchants to penetrate into the film deeper. However, at k value of 2.7, the low-k film deposited using the conventional precursor has ˜300 Å thick PID layer, while the low-k film deposited using the film forming composition disclosed in the present disclosure has ˜150 Å thick PID layer. The test results in FIG. 4 illustrate that a low-k material film formed using the film forming composition according to an embodiment of the present disclosure has more plasma-resistance than a low-k material film that is formed using the conventional precursor composition.

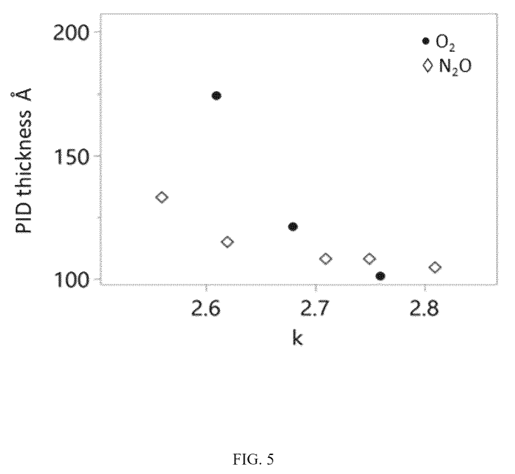

FIG. 5 illustrates a plasma induced damage layer thickness (“PID layer” thickness) versus k-value of PE-CVD deposited films using a film forming composition comprising a siloxane precursor according to the present disclosure and an oxidizing plasma formed from an O₂ containing feed gas (circles) and a N₂O containing feed gas (diamonds). In general, the PID thickness increases as the k-value of the film decreases. However, at k values of less than 2.7, the films deposited with O₂ containing feed gas have a thicker PID layer than the films deposited with N₂O containing feed gas.

UV irradiation may increase the elastic modulus of the film and this may be another advantageous factor of the methods and systems disclosed herein. In an example, a low-k material film was produced via the PE-CVD methods described herein but with no UV curing. The film had an elastic modulus of 10 GPa and a k-value of 2.75. In another example, a low-k material film was produced via the PE-CVD methods described herein with UV curing. The film had an elastic modulus of 12 GPa and a k-value of 2.77. These examples illustrate that, for a given k-value, UV curing increases the elastic modulus of the film.

Although certain embodiments and examples are disclosed herein, it will be understood by those skilled in the art that the disclosed compositions, methods, and systems, extend beyond the specifically disclosed embodiments and include all novel and nonobvious combinations and sub-combinations of the various compositions, methods, and systems, as well as any and all equivalents thereof. It is to be understood that the compositions, methods, and systems described herein are exemplary in nature, and that these specific embodiments or examples are not to be considered in a limiting sense, because numerous variations are possible. The specific methods and systems described herein may represent one or more of any number of processing strategies. Thus, the various acts illustrated may be performed in the sequence illustrated, in other sequences, or omitted in some cases. Moreover, various features of the disclosure are grouped together in one or more, aspects, embodiments, and configurations for the purpose of streamlining the disclosure. The features of the aspects, embodiments, and configurations of the disclosure may be combined in alternate aspects, embodiments, and configurations other than those discussed above. The compositions, methods, and systems of the disclosure are not to be interpreted as reflecting an intention that the claimed disclosure requires more features than are expressly recited in each claim. Rather, as the following claims reflect, inventive aspects lie in less than all features of a single foregoing disclosed aspect, embodiments, and configurations. Thus, the following claims are hereby incorporated into this Detailed Description, with each claim standing on its own as a separate embodiment of the disclosure, and the features recited in the various dependent claims may be combined with one another in various combinations, as appropriate, to form other embodiments of the disclosure.

1. A method for forming a low-k material film on a surface of a substrate, the method comprising:
providing a substrate comprising a surface in a reaction chamber;
introducing a vapor of a film forming composition into the reaction chamber;
introducing a feed gas into the reaction chamber; and
forming a plasma in the reaction chamber,
wherein the steps of introducing the vapor of the film forming composition, introducing the feed gas, and forming the plasma in the reaction chamber at least partially overlap,
wherein the film forming composition comprises a silicon precursor having a structure according to a general Formula (1): 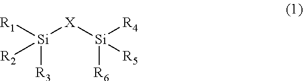
wherein, X is selected from an O atom, an NH group, and a CH₂ group; and R¹, R², R³, R⁴, R⁵, and R⁶ are each a substituent group independently selected from a hydrogen atom, a C₁-C₆ alkyl group, a C₂-C₆ alkenyl group, and a C₁-C₆ alkoxy group with the proviso that at least one of R¹, R², R³, R⁴, R⁵, and R⁶ is a methyl group (CH₃),
wherein a ratio of the silicon precursor to the feed gas is between 5:1 and 1:40.

2. The method of claim 1, wherein in the general Formula (1), at least two of R¹, R², R³, R⁴, R⁵, and R⁶ are methyl groups.

3. The method of claim 1, wherein in the general Formula (1), the substituent R¹ is selected from a C₂-C₆ alkenyl group; and the substituents R², R³, R⁴, R⁵, and R⁶ are each independently selected from a hydrogen atom and a C₁-C₆ alkyl group with the proviso that at least one of R², R³, R⁴, R⁵, and R⁶ is a methyl group.

4. The method of claim 1, wherein in the general Formula (1), the substituent R¹ is selected from a C₁-C₆ alkoxy group; and the substituents R², R³, R⁴, R⁵, and R⁶ are each independently selected from a hydrogen atom and a C₁-C₆ alkyl group with the proviso that at least one of R², R³, R⁴, R⁵, and R⁶ is a methyl group.

5. The method of claim 1, wherein in the general Formula (1), the substituents R¹ and R⁴ are each a C₂-C₆ alkenyl group; and the substituents R², R³, R⁵, and R⁶ are each independently selected from a hydrogen atom and a C₁-C₆ alkyl group with the proviso that at least two of R², R³, R⁵, and R⁶ are methyl groups.

6. The method of claim 1, wherein in the general Formula (1), the substituents R¹ and R⁴ are each a C₁-C₆ alkoxy group; and the substituents R², R³, R⁵, and R⁶ are each independently selected from a hydrogen atom and a C₁-C₆ alkyl group with the proviso that at least two of R², R³, R⁵, and R⁶ are methyl groups.

7. The method of claim 1, wherein X is an O atom.

8. The method of claim 1, wherein X is an NH group.

9. The method of claim 1, wherein X is a CH₂ group.

10. The method of claim 7, wherein the silicon precursor is selected from the group consisting of: 1,3-dimethyl-1,3-divinyldisiloxane, 1,1,3,3-tetramethyl-1-vinyldisiloxane, 1,1,3,3,3-pentamethyl-1-vinyldisiloxane, 1,1,3,3-tetramethyl-1,3-divinyldisiloxane, 4-methyl-1,1,3,3-tetramethyldisiloxane, 4-ethyl-1,1,3,3-tetramethyldisiloxane, 4-methyl-1,1,1,3,3-pentamethyldisiloxane, 4-ethyl-1,1,1,3,3-pentamethyldisiloxane, 1,3-dimethoxy-1,3-dimethyldisiloxane, 1,3-diethoxy-1,3-dimethyldisiloxane, 1,3-dimethoxy-1,1,3,3-tetramethyldisiloxane, 1,3-diethoxy-1,1,3,3-tetramethyldisiloxane, 1,3-divinyl-1,3-dimethyl-1,3-dimethoxydisiloxane, 1,1,3,3-tetramethyldisiloxane, and hexamethyldisiloxane.

11. The method of claim 8, wherein the silicon precursor is selected from the group consisting of: 1,3-dimethyl-1-vinyldisilazane, 1,1,3,3-tetramethyl-1-vinyldisilazane, 1,1,3,3,3-pentamethyl-1-vinyldisilazane, 1,3-dimethyl-1,3-divinyldisilazane, 1,1,3,3-tetramethyl-1,3-divinyldisilazane, 1,1,3,3-tetramethyldisilazane, and hexamethyldisilazane.

12. The method of claim 9, wherein the silicon precursor is selected from the group consisting of: 2,4,4-trimethyl-5-oxa-2,4-disilahexane, 2,4,4-trimethyl-5-oxa-2,4-disilaheptane, 2,2,4,4-tetramethyl-5-oxa-2,4-disilahexane, 2,2,4,4-tetramethyl-5-oxa-2,4-disilaheptane, 3,3,5,5-tetramethyl-2,6-dioxa-3,5-disilaheptane, 3,3,5,5-tetramethyl-2,6-dioxa-3,5-disilanonane, 3,5-dimethoxy-3,5-dimethyl-2,6-dioxa-3,5-disilaheptane, ((dimethoxymethylsilyl)methyl)trimethylsilane, and ((methoxymethylsilyl)methyl)ethenyldimethylsilane.

13. The method of claim 1, wherein the low-k material film comprises at least about 20 at. % of carbon.

14. The method of claim 1, wherein the method further comprises maintaining the reaction chamber at a pressure of at least about 0.5 Torr and no more than about 100 Torr.

15. The method of claim 1, wherein the method further comprises maintaining a temperature of the substrate at least about 50° C. and no more than about 500° C.

16. The method of claim 1, wherein the feed gas comprises one or more of N₂O, O₂, Ar, and He.

17. The method of claim 1, wherein the plasma comprises a capacitively coupled plasma (CCP).

18. The method of claim 1, wherein the plasma is formed by applying a high-frequency RF power and/or a low-frequency RF power, wherein a frequency of the high-frequency RF power is at least about 13.56 MHz and a frequency of the low-frequency RF power is no more than about 2 MHz.

19. The method of claim 1, further comprising: irradiating the surface of the substrate with UV radiation.

20. A precursor delivery vessel configured to provide a flow of a film forming composition, the precursor delivery vessel comprising:
an outer wall that encloses a cavity;
an outlet seated in the outer wall and in fluid communication with the cavity;
a film forming composition impounded in the cavity, wherein the film forming composition comprises a silicon precursor having a structure according to a general Formula (1): 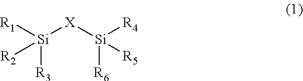
wherein, X is selected from an O atom, an NH group, and a CH₂ group; and R¹, R², R³, R⁴, R⁵, and R⁶ are each a substituent group independently selected from a hydrogen atom, a C₁-C₆ alkyl group, a C₂-C₆ alkenyl group, and a C₁-C₆ alkoxy group with the proviso that at least one of R¹, R², R³, R⁴, R⁵, and R⁶ is a methyl group (CH₃).

21. A substrate processing apparatus for forming a low-k material film comprising:
a vapor deposition assembly comprising:
a reaction chamber comprising a first susceptor for accommodating a substrate;
a film forming composition source comprising a film forming composition in fluid communication with the reaction chamber via a film forming composition source valve, wherein the film forming composition comprises a silicon precursor having a structure according to a general Formula (1): 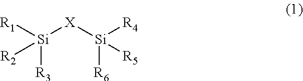
wherein, X is selected from an O atom, an NH group, and a CH₂ group; and R¹, R², R³, R⁴, R⁵, and R⁶ are each a substituent group independently selected from a hydrogen atom, a C₁-C₆ alkyl group, a C₂-C₆ alkenyl group, and a C₁-C₆ alkoxy group with the proviso that at least one of R¹, R², R³, R⁴, R⁵, and R⁶ is a methyl group (CH₃);
a feed gas source comprising a feed gas in fluid communication with the reaction chamber via a feed gas source valve;
a plasma unit comprising a power generator; and
a controller operably connected to the film forming composition source valve, the feed gas source valve, and the power generator, wherein the controller is configured and programmed to control:
supplying the film forming composition to the reaction chamber;
supplying the feed gas to the reaction chamber; and
activating the power generator to form a plasma in the reaction chamber,
wherein the steps of supplying the film forming composition, supplying the feed gas, and activating the power generator at least partially overlap and result in the formation of the low-k material film on a surface of the substrate.
